(19) United States
(12) Patent Application Publication
(10) Pub. No.: US 2008/0223439 A1
(43) Pub. Date: Sep. 18, 2008

(54) Interconnected Photoelectrochemical Cell

(76) Inventors: Xunming Deng, Sylvania, OH (US); Liwei Xu, Sylvania, OH (US)

Correspondence Address: MACMILLAN SOBANSKI & TODD, LLC, ONE MARITIME PLAZA FIFTH FLOOR, 720 WATER STREET, TOLEDO, OH, 43604-1619, US

(21) Appl. No.: 10/589,691

(22) PCT Filed: Feb. 18, 2005
(86) PCT No.: PCT/US2005/005121

§ 371 Date: Aug. 17, 2006

Related U.S. Application Data
(60) Provisional application No. 60/545,892, filed on Feb. 19, 2004.

(51) Int. Cl. H01L 31/0368; H01L 31/042; H01L 31/0264; H01L 31/18

(52) U.S. Cl. 136/258; 136/244; 136/260; 136/261; 438/73; 438/97; 257/E31.004; 257/E31.043

(57) ABSTRACT

An interconnected photoelectrochemical (PEC) cell (1) generates hydrogen and oxygen from water while being illuminated with radiation such as sunlight. The photovoltaic structure in the photoelectrode is deposited on a transparent and insulating substrate (also called superstrate) (3) that is covered with a transparent conducting layer (front electrode) (4). The front electrode is electrically connected to the back side of the photovoltaic structure such that the PLC cell can be made with high efficiency and high durability and at low cost. Three types of photoelectrodes and phtoelectrochemical cells are illustrated as examples.

The instant invention relates generally to the generation of hydrogen and oxygen from water through a photo-electrolysis process and more particularly to the generation of hydrogen using solar radiation. This invention was made with Government support under AFRL-WPAFB Grant “Photovoltaic Hydrogen for Portable, On-Demand Power” awarded to the University of Toledo under subcontract 03-S530-0011-01C1 under the primary contract F33615-02-D-2299 through the Universal Technology Corporation and under NSF-Partnership For Innovation Program awarded to the University of Toledo and sub-awarded to Midwest Optoelectronics. The government has certain rights in this invention.

### BACKGROUND OF THE INVENTION

### Field of the Invention

Future transportation is widely believed to be based on a hydrogen economy. Using fuel cells, cars and trucks will no longer burn petroleum and will no longer emit CO₂ on the streets since they will use hydrogen as the fuel and the only byproduct is water. However, the reforming process, the main process that is used in today's hydrogen production, still uses petroleum-based products as the raw material and still emits large amounts of CO₂. To reduce our society's reliance on petroleum based products and to avoid the emission of CO₂ that causes global warming, a renewable method of generating hydrogen must be developed. An electrolysis process using only sunlight and water is considered to be a top choice for hydrogen generation. Such hydrogen fuel is ideal for proton exchange membrane fuel cell (PEMFC) applications since it contains extremely low concentrations of undesirable carbon monoxide, which is poisonous to platinum catalysts in PEM fuel cells. However, indirect photoelectrolysis, in which the photovoltaic cells and electrodes are separated and connected electrically using external wires, is not cost-effective. An integrated photoelectrochemical cell (PEC) offers the potential to generate hydrogen renewably and cost effectively.

Several prior inventions and publications have disclosed designs for photoelectrochemical cells. U.S. Pat. No. 4,090,933 (Nozik), U.S. Pat. No. 4,144,147 (Jarrett et al.), U.S. Pat. No. 4,236,984 (Grantham), U.S. Pat. No. 4,544,470 (Hetrick), U.S. Pat. No. 4,310,405 (Heller), U.S. Pat. No. 4,628,013 (Figard et al.), U.S. Pat. No. 4,650, 554 (Gordon), U.S. Pat. No. 4,656,103 (Reichman et al.), U.S. Pat. No. 5,019,227 (White et al.), U.S. Pat. No. 6,471,850 (Shiepe et al.), U.S. Pat. No. 6,361,660 (Goldstein), U.S. Pat. No. 6,471,834 (Roe et al.).

J. R. Bolton “Solar photoproduction of hydrogen: a review”, Solar Energy, 57, 37 (1996).

S. S. Kocha, D. Montgomery, M. W. Peterson, J. A. Turner, “Photoelectrochemical decomposition of water utilizing monolithic tandem cells”, Solar Energy Materials & Solar Cells, 52, 389(1998).

S. Licht, “Efficient solar generation of hydrogen fuel—a fudamental analysis”, Electrochemistry Communications 4, 790 (2002).

P. K. Shukla, R. K. Karn, A. K. Singh, O. N. Srivastava, “Studies on PV assisted PEC solar cells for hydrogen production through photoelectrolysis of water”, Int. J. of Hydrogen Energy, 27, 135 (2002).

X. Gao, S. Kocha, A. Frank, J. A. Turner, “Photoelectrochemical decomposition of water using modified monolithic tandem cells”, In. J. of Hydrogen Energy, 24, 319 (1999).

R. E. Rocheleau and E. L. Miller, “Photoelectrochemical production of hydrogen: Engineering loss analysis”, Int. J. Hydrogen Energy, 22, 771 (1997).

However, the prior art devices and methods described and disclosed in these above mentioned patents and publications have at least one of the following shortcomings:

the photovoltaic cell does not generate sufficient voltage to split water the photovoltaic cell needs an external electrical bias for the electrolysis,

the photovoltaic device will not survive for extended use in the electrolyte due to inappropriate protection,

the photovoltaic device cannot be fabricated using low-cost methods, and

the photovoltaic device does not have potential for high conversion efficiency.

Two patent applications were recently filed by the inventors of this invention, PCT/US03/37733 filed Nov. 24, 2003 (claiming priority from Ser. No. 60/428,841 filed Nov. 25, 2002) and PCT/US03/37543 filed Nov. 24, 2003 (claiming priority from Ser. No. 60/429,753 filed Nov. 25, 2002). In these earlier inventions, multiple-junction thin-film solar cells are used as photoelectrodes for photoelectrochemical production of hydrogen and the photoelectrodes are not deposited on insulation and transparent substrates or superstrates. In these photoelectrodes, the front electrical contact, (front electrode, front contact) are not sandwiched between the insulating substrate and the semiconductor layers.

Solar cells deposited on a glass substrate (often referred also as glass superstrate due to the direction of the sunlight) have been widely fabricated for conversion of sunlight to electricity. These solar cells have reached high efficiency. However, being deposited on non-conducting substrates, the front electrical contact of such a solar cell is sandwiched between the substrates and the semiconductor layers. therefore, such a solar cell cannot be directly used for photoelectrolysis to generate hydrogen. An innovative design is needed to allow electrical connection between the front contact and the anode or cathode which are in physical contact with the electrolyte.

In addition, several types of thin film solar cells, such as CdTe based and CIGS based solar cells, can be made with high conversion efficiency and at low cost, but efforts in making multiple-junction solar cells using CdTe and CIGS based solar cells have so far been unsuccessful. Therefore, these solar cells do not offer sufficient voltage to split water when used without interconnection. Other examples of such solar cells are single-junction thin-film silicon based solar cells, including amorphous silicon (a-Si), amorphous silicon germanium (a-SiGe), microcrystalline silicon (mx-Si), nanocrystalline silicon (nc-Si) based solar cells. Moreover, some double-junction thin-film silicon based solar cells, even with component cells stacked on top of each other, still do not provide sufficient voltage for efficient water electrolysis.

Therefore, there is a compelling and crucial need in the art for an innovative design for PEC photoelectrode and PEC device that could 1) allow photo-generated voltage from photovoltaic cells deposited on an insulating substrate to be applied onto anode and cathodes that are in contact with the electrolyte; 2) allow, in case that photo-generated voltage is not sufficient to split water, the voltage from neighboring subbcells being stacked in an integrated and cost-effective manner, to drive electrolysis of water, while at the same time, maintaining the functionality of the PEC operation, 3) be used to generated hydrogen efficiently over extended period of time, and 4) be fabricated at low cost.

### SUMMARY OF THE INVENTION

In one aspect, the present invention relates to a photoelectrode having a substrate that is transparent and insulating; a transparent conducting layer deposited on the substrate as a front electrode (Electrode A) for a photovoltaic cell; single-junction semiconductor pn or pin layers, or multiple-junction stacked pin or pin layers, that generate photovoltage under illumination; a back contact layer which is electrically conductive to form Electrode B, which may be either cathode or anode but is opposite to Electrode A; an insulating layer that covers portions of the back contact; a conducting layer, that is electrically connected to the transparent conducting layer (Electrode A) the conducting layer being either anode or cathode depending on the polarity of the photovoltaic cell, but is opposite to Electrode B; an oxygen evolution reaction layer; and an hydrogen evolution reaction layer, to cover all or portions of anode and cathode, respectively, and to protect the photovoltaic cell from chemical and electrochemical corrosion.

In certain embodiments, at least some of the transparent conducting layer, photovoltaic layers, and the back-contact layer are electrically separated into smaller-area subcells, with each subcell group containing both anode and cathode, so that the photoelectrode is functionally separated into a multiple of sub-photoelectrodes. Further, the sub-cells can be separated by scribe lines where the scribe lines are at least one of laser scribed lines, mechanical scribed lines, or chemical scribed lines by screen-printing of chemical etching paste.

In another aspect, the photoelectrode comprises a first scribing which removes predetermined portions of the TCO front contacts from the insulating substrates, thus electrically isolating the TCO sheets into subcells; a second scribing which removes predetermined portions of the thin-film semiconductor layers; a third scribing which removes predetermined portions of the back metal contact layer from the semiconductor layers; the first, second and third scribings being scribed together, thereby connecting the front TCO contact of one strip cell with the back contact of the neighboring strip cell; a fourth scribing, which removes predetermined portions of the back metal contact from the thin-film semiconductor layers, approximately at or near the position of the first scribe line, such that the small segment between the third and fourth scribe lines is electrically connected to the front electrode (Electrode A) and is electrically isolated from rest of the back contact (Electrode B); and catalyst layers for electrolysis, when needed, applied onto, or electrically connected with, selected areas of the anode or cathode.

The photoelectrode can comprise solar cells that do not generate sufficient voltage for water electrolysis under illumination. The fourth scribing is applied for every other (or every third, etc) subcell, connecting two (or three, etc) subcells into a unit cell, which, with added voltage from a multiple of subcells connected together, has voltage sufficient to drive water electrolysis; appropriate insulating layer cover predetermined areas of the back contact so that only the anode and cathodes are exposed to electrolyte; and the conducting layer, electrically connected to front electrode (Electrode A) via the segment between the third and fourth scribes, is deposited at predetermined areas on top of the insulating layer.

In certain embodiments, the solar cells comprise at least one of single-junction solar cell or low-voltage double-junction solar cells. The photovoltaic cell can comprise single-junction thin-film silicon based solar cells such as single-junction (SJ) amorphous silicon (a-Si), SJ amorphous silicon germaninum (a-SiGe), SJ microcrystalline silicon (mx-Si), SJ nanocrystalline silicon (nc-Si); single-junction (SJ) polycrystalline solar cells such as SJ cadmium telluride based solar cells, SJ CuInSe2 based solar cells, SJ CuInGaSe2 based solar cells; or, double-junction solar cells that consists of one or two of a-Si, a-SiGe, mx-Si, nc-Si, CdTe, CuInSe2, and CuInGaSe2 based solar cells.

In other aspects, the photoelectrode include photovoltaic cells that comprise solar cells that do generate sufficient voltage for water electrolysis under illumination, where the fourth scribing is applied for every subcell, an appropriate insulating layer covers predetermined areas of the back contact so that only the anode and cathodes are exposed to electrolyte, and the conducting layer, electrically connected to front electrode (Electrode A) via the segment between the third and fourth scribes, is deposited at predetermined areas on top of the insulating layer. The photoelectrode can include solar cells which comprise at least one of triple-junction solar cells or high-voltage double-junction solar cells.

Further, the photoelectrode can include photovoltaic cells comprising a double-junction solar cell that consists of one or two of a-Si, a-SiGe, mx-Si, nc-Si, CdTe, CuInSe2, and CuInGaSe2 based solar cells; a triple-junction solar cell that consists of one or more of a-Si, a-SiGe, mx-Si, nc-Si, CdTe, CuInSe2, and CuInGaSe2 based solar cells; or a quadruple-junction solar cell that consists of one or more of a-Si, a-SiGe, mx-Si, nc-Si, CdTe, CuInSe2, and CuInGaSe2 based solar cells.

In one aspect, the anode or cathode, or both, may be extended beyond the surface of the photovoltaic cell and back contact layer. The front electrode (Electrode A) is electrically connected to a separate conducting layer which is not in contact with the Electrode B, via the segment between the third and fourth scribes.

In other embodiments, the solar cells can comprise at least one of triple-junction solar cells or high-voltage double-junction solar cells. The photovoltaic cell can comprise a double-junction solar cell that consists of one or two of a-Si, a-SiGe, mx-Si, nc-Si, CdTe, CuInSe2, and CuInGaSe2 based solar cells; a triple-junction solar cell that consists of one or more of a-Si, a-Sige, mx-Si, nc-Si, CdTe, CuInSe2, and CuInGaSe2 based solar cells; or a quadruple-junction solar cell that consists of one or more of a-Si, a-Sige, mx-Si, nc-Si, CdTe, CuInSe2, and CuInGaSe2 based solar cells.

Yet another aspect of the present invention relates to a method of making a photoelectrode which includes

selecting a substrate that is transparent and insulating;

forming a transparent conducting layer on the substrate as a front electrode (Electrode A) for a photovoltaic cell;

forming single-junction semiconductor pn or pin layers, or multiple-junction stacked pin or pin layers, that generate photovoltage under illumination;

forming a back contact layer which is electrically conductive to form Electrode B, which may be either cathode or anode but is opposite to Electrode A;

forming an insulating layer that covers portions of the back contact;

forming a conducting layer, that is electrically connected to the transparent conducting layer (Electrode A), the conducting layer being either anode or cathode depending on the polarity of the photovoltaic cell, but being opposite to Electrode B; and

forming an oxygen evolution reaction layer and a hydrogen evolution reaction layer to cover all or portions of the anode and the cathode, respectively, and to protect the photovoltaic cell from chemical and electrochemical corrosion.

The method can further comprise where at least some of the transparent conducting layer, photovoltaic layers, and the back-contact layer are electrically separated into smaller-area subcells with each subcell group containing both anode and cathode, so that the photoelectrode is functionally separated into a multiple of sub-photoelectrodes. Also, the sub-cells can be separated by scribe lines formed be at least one of laser scribing, mechanical scribing, or chemical scribing by screen-printing of chemical etching paste.

The method can further include:

forming a first scribing which removes predetermined portions of the TCO front contacts from the insulating substrates, thus electrically isolating the TCO sheets into subcells;

forming a second scribing which removes predetermined portions of the thin-film semiconductor layers;

forming a third scribing which removes predetermined portions of the back metal contact layer from the semiconductor layers;

the first, second and third scribings being scribed together, thereby connecting the front TCO contact of one strip cell with the back contact of the neighboring strip cell;

forming a fourth scribing, which removes predetermined portions of the back metal contact from the thin-film semiconductor layers, approximately at or near the position of the first scribe line, such that the small segment between the third and fourth scribe lines is electrically connected to the front electrode (Electrode A) and is electrically isolated from rest of the back contact (Electrode B); and, optionally

forming catalyst layers for electrolysis, when needed, applied onto, or electrically connected with, selected areas of the anode or cathode.

Also, the photovoltaic cells can comprise solar cells that do not generate sufficient voltage for water electrolysis under illumination. The fourth scribing can be applied for every other (or every third, etc) subcell, connecting two (or three, etc) subcells into a unit cell, which, with added voltage from a multiple of subcells connected together, has voltage sufficient to drive water electrolysis; and appropriate insulating layer covers predetermined areas of the back contact so that only the anode and cathodes are exposed to electrolyte.

In yet another aspect, the solar cells comprise at least one of single-junction solar cell or low-voltage double-junction solar cells. The photovoltaic cell comprises at least one of: single-junction thin-film silicon based solar cells such as single-junction (SJ) amorphous silicon (a-Si), SJ amorphous silicon germaninum (a-SiGe), SJ microcrystalline silicon (mx-Si), SJ nanocrystalline silicon (nc-Si); single-junction (SJ) polycrystalline solar cells such as SJ cadmium telluride based solar cells, SJ CuInSe2 based solar cells, SJ CuInGaSe2 based solar cells; or double-junction solar cells that consists of one or two of a-Si, a-SiGe, mx-Si, nc-Si CdTe, CuInSe2, and CuInGaSe2 based solar cells.

Also, the photovoltaic cells can comprise solar cells that do generate sufficient voltage for water electrolysis under illumination, the fourth scribing is applied for every subcell, and an appropriate insulating layer covers predetermined areas of the back contact so that only the anode and cathodes are exposed to electrolyte. The solar cells comprise at least one of triple-junction solar cells or high-voltage double-junction solar cells. The photovoltaic cell comprises: a double-junction solar cell having one or two of a-Si, a-Sige, mx-Si, nc-Si, CdTe, CuInSe2, and CuInGaSe2 based solar cells; a triple-junction solar cell having one or more of a-Si, a-Sige, mx-Si, nc-Si, CdTe, CuInSe2, and CuInGaSe2 based solar cells, or a quadruple-junction solar cell having one or more of a-Si, a-Sige, mx-Si, nc-Si, CdTe, CuInSe2, and CuInGaSe2 based solar cells.

In still another aspect, the present invention relates to a photoelectrochemical cell comprising:

a photoelectrode,

an electrolyte, either alkaline or acidic, with which both anode and cathode are in contact;

compartments for oxidation reaction where oxygen is generated;

compartments for reduction reaction where hydrogen is generated;

ion conduction layers placed between a oxidation compartment and a reduction compartment; and

an enclosure that confines the electrolyte for electrolysis.

The photoelectrochernical cells produce hydrogen under radiation from the sun.

### BRIEF DESCRIPTION OF THE DRAWINGS

FIG. 1 is a schematic diagram of the front view of a section of a first type of PEC cell employing a single-junction photovoltaic cell, showing the layers of the PV electrode, the scribe lines, the insulating layer, the catalyst layers, the membrane, and the compartments separated by the membrane.

FIG. 2 is a schematic diagram of the front view of a section of a second type of PEC cell employing a triple-junction photovoltaic cell, showing the layers of the PV electrode, the scribe lines, the insulating layer, the catalyst layers, the membrane, and the compartments separated by the membrane.

FIG. 3 is a schematic diagram of the front view of a section of the third-type of PEC cell employing a triple-junction photovoltaic cell, showing the layers of the PV electrode, the scribe lines, the insulating layer, the catalyst layers, the membrane, and the compartments separated by the membrane.

### DETAILED DESCRIPTION OF THE PREFERRED EMBODIMENTS

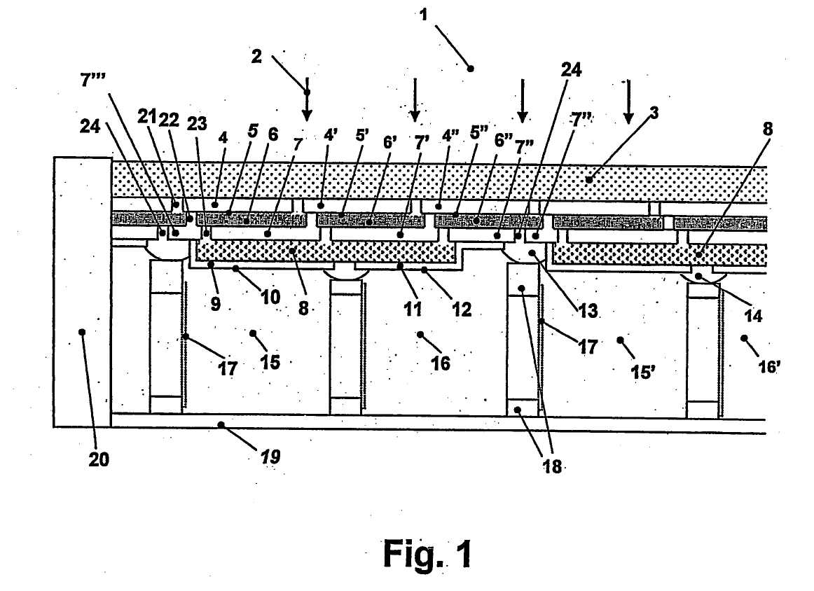

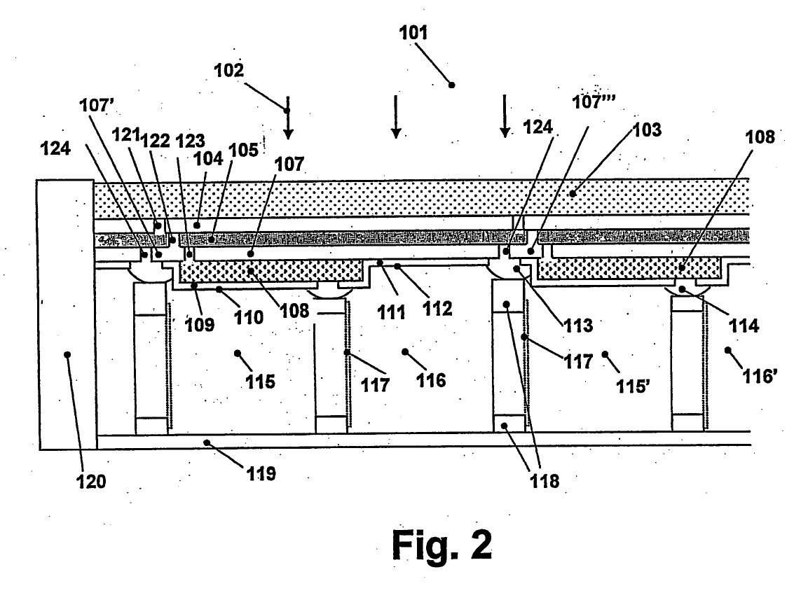

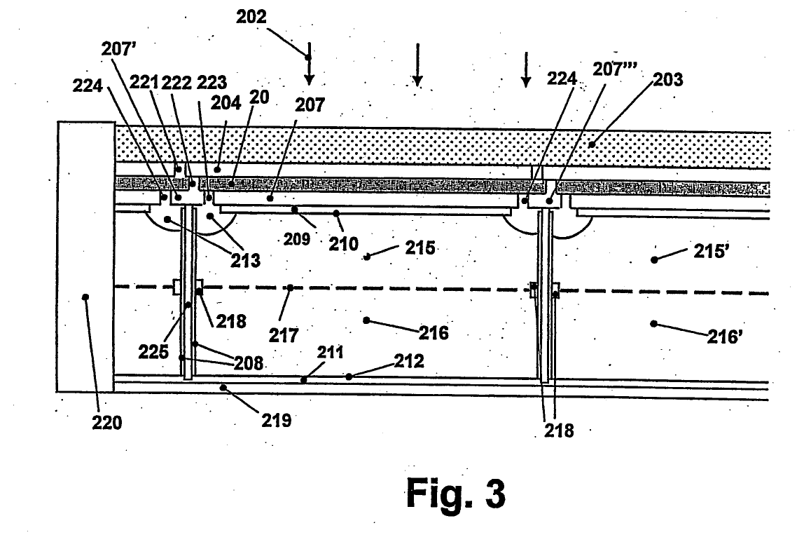

The instant invention provides a photoelectrochemical (PEC) cell that splits water under radiation and generates hydrogen and oxygen. In this PEC cell, a photovoltaic (PV) electrode, illustrated in FIG. 1, FIG. 2 and FIG. 3, comprised of solar cells, appropriately interconnected, and appropriate coatings and catalysts, are placed in contact with an electrolyte, either acidic or alkaline. Under radiation such as sunlight, the PV electrode generates a voltage. The interconnect schemes allow the voltage for the solar cell to be applied to the anode and cathode that are in contact with electrolyte. The interconnect also allows the voltage to stack up, in case of single-junction solar cells as an example, and become sufficient to drive electrolysis and produce hydrogen and oxygen. A membrane is installed in the PEC cell to allow exchange of ions for the electrolysis yet confines the hydrogen and oxygen gases into two different compartments of the cell.

### The Photoelectrode

The photoelectrode of the present invention uses either a single-junction solar cell, with two or three of the single-junction solar cell subcell strips connected in series to provide sufficient voltage, or a multiple-junction solar cells such as double or triple-junction solar cells. Examples of the single-junction solar cells are amorphous silicon (a-Si) based solar cells, amorphous silicon germanium (a-SiGe) based solar cells, nanocrystalline silicon (nc-Si) based solar cells, microcrystalline silicon (mx-Si) based solar cells, polycrystalline silicon (poly-Si) based solar cells, cadmium telluride (CdTe) based solar cells, copper indium diselenide (CuInSe2) and copper indium gallium diselenide (CuInGaSe2) based solar cells. The photoelectrode comprises:

1) a substrate that is transparent and insulating; examples are glass and plastic;

2) a transparent conducting layer deposited on the substrate as the front electrode (Electrode A) for a photovoltaic cell; examples are tin oxide, zinc oxide, indium oxide and indium tin oxide;

3) single-junction semiconductor pn or pin layers, or multiple-junction stacked pin or pin layers, that generate photovoltage under illumination; examples are a-Si:H, a-SiGe:H, nc-Si:H, μc-Si:H, and poly-Si:H based pin layers or pn layers; CdS/CdTe based solar cells including alloys of CdTe and CdS with other elements; CIS and CIGS based solar cells including alloys of CuInSe₂ with other elements;

4) a back contact layer which is electrically conductive to form electrode B, which may be either cathode or anode but is opposite to Electrode A; examples are Cu, Al, Mo, Ag, Ni and other suitable materials;

5) an insulating layer that covers portions of the back contact;

6) a conducting layer, that is electrically connected to the transparent conducting layer (Electrode A); this conducting layer may be either anode or cathode depending on the polarity of the photovoltaic cell, but is opposite to Electrode B;

7) an oxygen evolution reaction layer and a hydrogen evolution reaction layer, to cover all or portions of anode and cathode, respectively, and to protect the photovoltaic cell from chemical and electrochemical corrosion.

### The Interconnection of Solar Cell Strips

A photoelectrode is separated into strip cells by scribe-lines formed using techniques such as laser scribing, mechanical scribing or chemical scribing by screen-printing of chemical etching paste. Two or more of these strip cells may be electrically connected together, when necessary, to provide voltage sufficient for water electrolysis. In one example, four scribing steps are employed to achieve the following objectives:

1) the photovoltaic layers, and the back-contact layer are electrically separated into smaller-area subcells, such as strip cells, with each unit cell (one or several subcells connected together electrically) containing both anode and cathode, so that the photoelectrode is functionally separated into a multiple of sub-photoelectrodes; an example of the width of a strip cell is 1 cm;

2) In case of single-junction solar cell or low-voltage double-junction solar cells, three strip cells (or two strip cells depending on the voltage of the solar cell) are connected together electrically to stack up the voltage provided by the cells to achieve efficient water electrolysis; and

3) each segment, containing one or multiple subcells, is electrically isolated from the neighboring segments and each of these segments forms a photoelectrochemical unit cell.

One embodiment of the four-step scribing process comprises:

1) conducting a first scribing to remove predetermined areas of the TCO front contacts from the insulating substrates thus electrically isolates the TCO sheets into subcells such as strip cells. A typical width of the strips is in the order of ˜1 cm;

2) conducting a second scribing to remove predetermined areas of the thin-film semiconductor layers from TCO layer;

3) conducting a third scribing to remove predetermined areas of the back metal contact layer from the semiconductor layers;

4) scribing the first scribing through the third scribing adjacent to one other, connecting the front TCO contact of one strip cell with the back contact of the neighboring strip cell;

5) conducting a fourth scribing to remove predetermined areas of the back metal contact from the thin-film semiconductor layers; this fourth scribe line being approximately at or near the position of the first scribe line, such that the small segment between the third and fourth scribe lines is electrically connected to the front electrode (Electrode A) and is electrically isolated from rest of the back contact (Electrode B); and

6) applying catalyst layers for electrolysis, when needed, onto, or electrically connected with selected areas of the anode and cathode.

### The PEC Cell and Method for Fabricating the PEC Cell

The photoelectrode deposited on an insulating substrate as described above forms the top cover of the PEC cell. The PEC cell is separated into different compartments by ion conducting membrane or a porous membrane, or other materials that could allow ions to go through while separating hydrogen and oxygen in two separate compartments. Hydrogen and oxygen gasses are generated in alternating compartments. Insulating epoxy is used to seal the edges and comers of the compartment and covers the exposed area of the metal back contact from corrosion in electrolyte.

The instant invention further provides a method to fabricate the above-disclosed PEC cell.

The PEC cell described herein uses a small amount of electrolyte, making the system lightweight and portable. The PEC cell also increases the flow of electrolyte so that gas bubbles can be efficiently flushed out of, or removed from, the electrode surfaces.

The above disclosed PEC cell and system offer significant advantages such as high conversion efficiency, efficient electrolysis, low cost, and high durability. It is understood that, in certain embodiments, for PEM fuel cells (PEMFC) where Pt is used as a catalyst, Pt could be poisoned by CO gas, thus resulting in reduced performance. However, the hydrogen fuels generated using such a PEC system contain extremely low amount of carbon monoxide, making such hydrogen ideal for PEMFC. The above-mentioned PEC system, when used in combination with portable fuel cells, provides distributed, and portable, power generation. The energy can be stored in hydrogen form. Since there is radiation such as sunlight everyday, the required storage for such combined PEC/PEMFC system does not need to be large, thus resulting in reduced costs.

The foregoing has outlined in broad terms the more important features of the invention disclosed herein so that the detailed description that follows may be more clearly understood, and so that the contribution of the instant inventor to the art may be better appreciated. The instant invention is not to be limited in its appreciation to the details of the construction and to the arrangements of the components set forth in the following description or illustrated in the drawings. Rather, the invention is capable of other embodiments and of being practiced and carried out in various other ways not specifically enumerated herein. Finally, it should be understood that the phraseology and terminology employed herein are for the purpose of description and should not be regarded as limiting, unless the specification specifically so limits the invention.

### Cell Structure for First Type of PEC Cell

FIG. 1 shows a section of the photoelectrochemical cell 1 with a single-junction photovoltaic cell. Many thin film solar cells are useful as the photovoltaic structure. For example, this includes a-Si based solar cells, a-SiGe based solar cells, nanocrystalline silicon based solar cells, CdTe based solar cells and CuInGaSe₂ based solar cells.

Using a CdS/CdTe as the example of the thin film solar cell 1, the layers in the structure of the PEC cell, from top to bottom, are glass superstrate 3, tin oxide transparent conductor layer 4, CdS semiconductor layer 5, CdTe semiconductor layer 6, metal back contact layer 7, insulating layer 8, back electrode and catalyst layer 9 for hydrogen evolution reaction (HER) surface 10, and oxygen evolution reaction (OER) layer 11. Hydrogen evolves out at the HER surface 10 into a reduction compartment 15 and oxygen evolves out at an OER surface 12 into an oxidation compartment 16.

A four-step laser scribing is used to achieve cell interconnection. A first scribe is performed after the deposition of the tin oxide transparent conductor layer 4 (front electrical contact) on the superstrate 3. The first scribe removes predetermined areas of tin oxide 4 from the superstrate 3 to form the first scribe line 21. A second scribe is performed after the deposition of the semiconductor layers, such as CdS layer 5 and CdTe layer 6, onto the tin oxide transparent conductor layer 4. The second scribe removes predetermined portions of the semiconductor layers 5 and 6 from desired portions of the tin oxide transparent conductor 4 and forms the second scribe line 22. A third scribe is performed after the deposition of back metal contact 7 onto semiconductor layer 6. The third scribe removes predetermined portions of the back metal contact 7 from semiconductor layer 6 and forms the third scribe line 23. The first, second and third scribe lines, 21, 22 and 23 respectively, isolate the sheet of the photovoltaic cell into narrow and interconnected strip cells. The back contact 7 of a subcell #1 (or Strip Cell #1) (shown by 4,5,6 and 7) is electrically connected to the front contact 4′ of Strip Cell #2 (shown by 4′, 5′, 6′ and 7′). The back contact 7′ of Strip Cell #2 is electrically connected to the front contact 4″ of Strip Cell #3 (shown by 4″, 5″, 6″ and 7″).

According to one feature of the present invention a fourth scribe is performed together with the third scribe. The fourth scribe removes predetermined portions of the back metal contact 7″ from the semiconductor layer 6″ and forms the fourth scribe line 24. The fourth scribe is performed on every third strip of the back contact 7″, for a single-junction solar cell such as CdS/CdTe which has an open circuit voltage around 0.8V. Functionally, the fourth scribe line 24 electrically isolates a 3-strip cell segment from the neighboring segments. The small section 7′″ of the back contact is electrically connected to the front contact 4 of the Strip Cell #1, but is not electrically connected to the back contact 7″ of Strip Cell #3. Therefore, the fourth scribe lines 24 from the fourth scribe isolate the entire sheet of photoelectrodes into segments with each segment having three interconnected strip cells (i.e., shown as 4,5,6,7; shown as 4′, 5′, 6′, 7′; and shown as 4″, 5″, 6″, 7″).

An insulating layer 8 such as a corrosion-resistant paint, an epoxy or a polymer layer 8 is applied onto the photoelectrode to cover the back contact 7 of PV Strip Cell #1 and the back contact 7′ of PV Strip Cell#2.

The hydrogen evolution reaction catalyst 9, such as CoMo, is then applied onto the polymer layer 8, but in contact with the section of the metal back contact 7′″ isolated by the third and fourth laser scribing steps.

The oxygen evolution reaction catalyst 11, such as Fe:NiOₓ, titanium oxide or ruthenium oxide, is then applied on the back contact 7″ of PV Strip Cell #3.

A plastic shield 18 separates a container filled with electrolyte into the reduction compartment 15 (where a reduction half reaction occurs and hydrogen is produced) and into the oxidation compartment 16 (where an oxidation half reaction occurs and oxygen is produced). There are openings on these plastic shields 18. Ion conduction membranes 17 are installed at these openings to allow ions to exchange between the two compartments while keeping the.oxygen and hydrogen gases separated.

### Cell Structure for Second Type of PE Cell

FIG. 2 shows a section of the photoelectrochemical cell 101 with a triple-junction photovoltaic cell. Many thin film solar cells are useful as the photovoltaic structure. For example, this includes a-Si/a-Si/a-SiGe, a-Si/a-SiGe/a-SiGe, a-Si/a-Si/mx-Si, a-Si/a-SiGe/mx-Si, a-Si/mx-Si/mx-Si, a-Si/a-SiGe/nc-Si based solar cells. Some time, double-junction solar cells with high-voltage component cells, such as a-Si/a-Si double-junction solar cells may exhibit sufficient voltage without stacking up voltage from neighboring subcells.

Using an a-Si/a-Si/a-SiGe pinpinpin type solar cell as the example of the thin film solar cell, the layers in the structure of the PEC cell, from top to bottom, are glass superstrate 103, tin oxide transparent conductor layer 104, pinpinpin a-Si alloy based layers 105, metal back contact layer 107, insulating layer 108, back electrode and catalyst layer 109 with a hydrogen evolution reaction (HER) surface 110, and an oxygen evolution reaction (OER) layer 111. Hydrogen evolves out at the HER surface 110 into a reduction compartment 115 and oxygen evolves out at the OER surface 112 into an oxidation compartment 116.

A four-step laser scribing is used to achieve cell interconnection. The first scribe is performed after the deposition of the tin oxide transparent conductor layer 104 (front electrical contact) on the superstrate 103. The first scribe removes predetermined portions of tin oxide 104 from the superstrate 103 to form a first scribe line 121. The second scribe is performed after the deposition of the semiconductor layer 105, onto the tin oxide transparent conductor layer 104. The second scribe removes predetermined portions of the semiconductor layer 105 from desired portions of the tin oxide transparent conductor 104 and forms a second scribe line 122. The third scribe is performed after the deposition of the back metal contact 107 onto the semiconductor layer 105. The third scribe removes predetermined portions of the back metal contact 107 from semiconductor layer 105 and forms the third scribe line 123. The first, second and third scribe lines, 121, 122 and 123, respectively, isolate the sheet of photovoltaic cell into narrow and interconnected strip cells. The back contact 107 of subcell (shown as 104, 105 and 107) is electrically connected to the front contact of an adjacent subcell;

A fourth scribe is performed together with the third scribe. The fourth scribe removes predetermined portions of the back metal contact 107 from the semiconductor layer 105 and forms a fourth scribe line 124. The fourth scribe is performed on every strip of the back contact 107, for a triple-junction solar cell such as a-Si/a-SiGe/a-SiGe, which has an open circuit voltage around 2.3V. Functionally, the fourth scribe line 124 electrically isolates the back contact stripcells. The small section 107′″ of the back contact 107 is electrically connected to the front contact 104 of the Strip Cell #101, but is not electrically connected to the back contact 107 of an adjacent strip. Therefore, the scribe lines 124 from the fourth scribe isolate the entire sheet of photoelectrodes into segments.

The insulating layer 108 such as a corrosion-resistant paint, an epoxy or a polymer layer 108 is applied onto the photoelectrode to cover the back contact 107 of the subcell.

The hydrogen evolution reaction catalyst 109, such as CoMo, is then applied onto the polymer layer 108, but in contact with the section of the metal back contact 107′ isolated by the third and fourth laser scribing steps.

The oxygen evolution reaction catalyst 111, such as Fe:NiOₓ, titanium oxide or ruthenium oxide, is then applied on the back contact 107.

A plastic shield 118 separates a container filled with electrolyte into the reduction compartment 115 (where a reduction half reaction occurs and hydrogen is produced), and the oxidation compartment 116 (where an oxidation half reaction occurs and oxygen is produced). There are openings on these plastic shields 118. Ion conduction membranes 117 are installed at these openings to allow ions to exchange between the two compartments while keeping the oxygen and hydrogen gases separated.

### Cell Structure for the Third Type of PE Cell

FIG. 3 shows a section of the photoelectrocherical cell 201 with a triple-junction photovoltaic cell. Many thin film solar cells are useful as the photovoltaic structure

Using a a-Si/a-SiGe/a-SiGe structure as the example of the thin film solar cell, the layers in the structure of the PEC cell, from top to bottom, are glass superstrate 203, tin oxide transparent conductor layer 204, pinpinpin layers 205, metal back contact layer 207, insulating layer 208, back electrode and catalyst layer 209 for hydrogen evolution reaction (HER) layer 210 and oxygen evolution reaction (OER) layer 211. Hydrogen evolves out at the HER surface 210 into the reduction compartment 215 and oxygen evolves out at the OER surface 212 into an oxidation compartment 216.

A four-step laser scribing is used to achieve cell interconnection. The first scribe is performed after the deposition of the tin oxide transparent conductor layer 204 (front electrical contact) on the superstrate 203. The first scribe removes pretermined areas of tin oxide 204 from the superstrate 203 to form the first scribe line 221. The second scribe is performed after the deposition of the semiconductor layers 205, onto the tin oxide transparent conductor layer 204. The second scribe removes the semiconductor layers predetermined portions of semiconductor layers 205 from desired portions of the tin oxide transparent conductor 204 and forms the second scribe line 222. The third scribe is performed after the deposition of back metal contact 207 onto the semiconductor layer 205. The third scribe removes predetermined portions of the back metal contact 207 from the semiconductor layer 205 and forms the third scribe line 223 The first, second and third scribe lines, 221, 222 and 223, respectively, isolate the sheet of photovoltaic cell into narrow and interconnected strip cells. The back contact 207 of a subcell is electrically connected to the front contact 204′ of an adjacent subcell (strip cell).

The fourth scribe is performed together with the third scribe. The fourth scribe removes predetermined portions of the back metal contact 207 from the semiconductor layers 205 and forms the fourth scribe line 224. Functionally, the fourth scribe 224 electrically isolates a stripcell segment from the neighboring segments. The small section 207′″ of the back contact is electrically connected to the front contact 204, but is not electrically connected to the back contact 207 of the Strip Cell. Therefore, the scribe lines from the fourth scribe 224 isolate the entire sheet of photoelectrodes into segments.

An insulating layer 208 such as a corrosion-resistant paint, an epoxy or a polymer layer 208 is applied onto a connecting wire 225 as well as the edge areas 213 next to the third scribe 223 and the fourth scribe line 224.

The hydrogen evolution reaction catalyst 209, such as CoMo, is then applied onto the back electrode, but in contact with the section of the metal back contact 207′ isolated by the third and fourth laser scribing steps.

Oxygen evolution reaction catalyst 211, such as Fe:NiOₓ, titanium oxide or ruthenium oxide, is then applied on the bottom plate 219.

A plastic shield 218 separates a container filled with electrolyte into the reduction compartment 215 (where a reduction half reaction occurs and hydrogen is produced), and the oxidation compartment 216 (where an oxidation half reaction occurs and oxygen is produced). There are openings on these plastic shields 218. Ion conduction membranes 217 are installed at these openings to allow ions to exchange between the two compartments while keeping the oxygen and hydrogen gases separated.

### Fabrication Process

The PEC cells shows in FIGS. 1, 2, and 3 are fabricated with three separate pieces; a) the PEC electrode 1, 101, 201, 2) the membrane holders 18, 118, 218; and 3) the back plate 19, 119,219 and side walls 20, 120, 220.

For easy of explanation, the fabrication process will be only described in detail for FIG. 1, but it should be understood that it is within the contemplated scope of the present invention that, at the least, the embodiments shown in FIGS. 2 and 3 can be fabricated in a similar manner. The thin film PV structure (shown as 4, 5, 6, 7 in FIG. 1) is deposited on a glass superstrate 3 using the standard process currently used by thin film photovoltaic manufacturers. The four step scribing process is used, with the first 3-steps being the standard scribing for cell interconnection. The fourth scribing, applied at approximately the same location as the first scribe, but on only every third (or second) strip cell for a single-junction solar cell or a low-voltage double-junction solar cell, removes metal back contact from the thin film semiconductor layer and isolates all of the PV cell strips into 3-strip (2-strip or 1-strip) segments. Each three-strip (two-strip, 1-strip) segment constitutes a PEC unit cell.

An insulating and corrosion-resistant layer, such as a paint, an epoxy or a polymer layer, is applied on the back in selected areas to cover appropriate areas of the back side.

### Fabrication of the Gas Shields:

The gas shields are mounted onto the back plate 19 via screws or epoxy. One way to install it is to dip the gas shields in a shallow pan filled with epoxy so that epoxy is applied to the edge of the plastic strips. This gas isolator and back plate unit is then applied onto the photoelectrode to finish the PEC cell. For example, the gas shields 18, the bottom plate 19 and the side plate 20 could be one unit made using injection molding.

The above detailed description of the present invention is given for explanatory purposes. All references disclosed herein are expressly incorporated herein by reference. It will be apparent to those skilled in the art that numerous changes and modifications can be made without departing from the scope of the invention. Accordingly, the whole of the foregoing description is to be construed in an illustrative and not a limitative sense, the scope of the invention begin defined solely by the appended claims.

We Claim:

1. A photoelectrode comprising:
a substrate that is transparent and insulating;
a front contact layer comprising a transparent conducting layer deposited on the substrate as a front electrode (Electrode A) for a photovoltaic cell;
at least one of single-junction semiconductor pn or pin layers, or multiple-junction stacked pin or pin layers, that generate photovoltage under illumination;
a back contact layer which is electrically conductive to form a back Electrode B, which may be either a cathode or an anode but is opposite to the Electrode A;
an insulating layer that covers portions of the back contact layer;
a conducting layer that is electrically connected to the transparent conducting layer (Electrode A), the conducting layer being either anode or cathode depending on the polarity of the photovoltaic cell, but is opposite to Electrode B; and optionally
an oxygen evolution reaction layer; and further optionally, a hydrogen evolution reaction layer, adapted to cover all or portions of the anode and the cathode, respectively, and to protect the photovoltaic cell from chemical and electrochemical corrosion.

2. The photoelectrode of claim 1, wherein at least one of the transparent conducting layer, photovoltaic layers, and the back contact layer are electrically separated into smaller area subcells, with each subcell or a combination of subcells containing both an anode and a cathode so that the photoelectrode is functionally separated into a multiple of sub-photoelectrodes.

3. The photoelectrode of claim 2, wherein the subcells are separated by scribe lines.

4. The photoelectrode of claim 3 where in the scribe lines are at least one of laser scribed lines, mechanical scribed lines, or chemical scribed lines by screen-printing of chemical etching paste.

5. The photoelectrode of claim 3, comprising:
a first scribing adapted to remove predetermined portions of the front contact layer from the insulating substrates of at least one strip cell, thus electrically isolating the front contact layer into subcells;
a second scribing adapted to remove predetermined portions of at least one thin-film semiconductor layer;
a third scribing adapted to remove predetermined portions of the back metal contact layer from the semiconductor layers;
the first, second and third scribings adapted to being scribed adjacent to one another, thereby connecting the front contact layer of one strip cell with the back contact of a neighboring strip cell;
a fourth scribing adapted to remove predetermined portions of the back metal contact from the thin-film semiconductor layers, approximately at or near the position of the first scribe line, such that a small segment between the third and fourth scribe lines is electrically connected to the front electrode Electrode A) and is electrically isolated from rest of the back contact (Electrode B); and
optionally, at least one catalyst layer for electrolysis adapted to be electrically connected with selected areas of the anode or cathode.

6. The photoelectrode of claim 5, wherein:
the photovoltaic cell comprises solar cells that do not generate sufficient voltage for water electrolysis under illumination,
the fourth scribing is adapted to be applied to at least certain subcells, the fourth scribing being adapted to connect at least two subcells into a unit cell, which, with added voltage from a multiple of subcells connected together, has voltage sufficient to drive water electrolysis;
an appropriate insulating layer covering predetermined areas of the back contact so that surfaces not resistant to corrosion are protected; and
wherein the conducting layer, electrically connected to front electrode (Electrode A) via the segment between the third and fourth scribes, is deposited at predetermined areas on top of the insulating layer.

7. The photoelectrode of claim 6, wherein the solar cells comprise at least one of single-junction solar cell or low-voltage double-junction solar cells.

8. The photoelectrode of claim 7, wherein the photovoltaic cell comprises at least one of:
single-junction thin-film silicon based solar cells,
single-junction (SJ) polycrystalline solar cells; or
double-junction solar cells.

9. The photoelectrode of claim 8, wherein the single-junction thin-film silicon based solar cells comprises at least one of single-junction (SJ) amorphous silicon (a-Si), SJ amorphous silicon germanium (a-SiGe), SJ microcrystalline silicon (mx-Si), SJ nanocrystalline silicon (nc-Si).

10. The photoelectrode of claim 8, wherein single-junction (SJ) polycrystalline solar cells comprises at least one of SJ cadmium telluride based solar cells, SJ CuInSe2 based solar cells, SJ CuInGaSe2 based solar cells.

11. The photoelectrode of claim 8, wherein the double-junction solar cells comprises at least one of a-Si, a-SiGe, mx-Si, nc-Si, CdTe, CuInSe2, and CuInGaSe2 based solar cells.

12. The photoelectrode of claim 5, wherein:
the photovoltaic cells comprise solar cells that do generate sufficient voltage for water electrolysis under illumination,
the fourth scribing is applied for every subcell,
an appropriate insulating layer covers predetermined areas of the back contact so that surfaces not resistant to corrosion are protected, and
the conducting layer, electrically connected to front electrode (Electrode A) via the segment between the third and fourth scribes, is deposited at predetermined areas on top of the insulating layer.

13. The photoelectrode of claim 12, wherein the solar cells comprise at least one of triple-junction solar cells or high-voltage double-junction solar cells.

14. The photoelectrode of claim 13, wherein the photovoltaic cell comprises at least one of:
a double-junction solar cell comprising one or two of a-Si, a-SiGe, mx-Si, nc-Si, CdTe, CuInSe2, and CuInGaSe2 based solar cells;
a triple-junction solar cell comprising one or more of a-Si, a-SiGe, mx-Si, nc-Si, CdTe, CuInSe2, and CuInGaSe2 based solar cells, or
a quadruple-junction solar cell comprising one or more of a-Si, a-SiGe, mx-Si, nc-Si, CdTe, CuInSe2, and CuInGaSe2 based solar cells.

15. The photoelectrode of claim 5, wherein the anode or cathode, or both, are adapted to extend beyond a surface of the photovoltaic cell and back contact layer.

16. The photoelectrode of claim 15, wherein the front electrode (Electrode A) is electrically connected to a separate conducting layer which is not in contact with the Electrode B, via a segment between the third and fourth scribes.

17. The photoelectrode of claim 16, wherein:
the photovoltaic cells comprise solar cells that do generate sufficient voltage for water electrolysis under illumination,
the fourth scribing is adapted to be applied to every subcell,
appropriate insulating material covers exposed areas due to the third and fourth scribes to prevent these areas from corrosion by electrolyte, and
the conducting layer, electrically connected to the front electrode Electrode A) via the segment between the third and fourth scribes, is deposited on a separate plate such as a bottom plate of a photoelectrochemical cell, and
an electrical connector that electrically connects Electrode A and a separate plate is covered by a corrosion-resistant insulating layer.

18. The photoelectrode of claim 17, wherein the solar cells comprises at least one of triple-junction solar cells or high-voltage double-junction solar cells.

19. The photoelectrode of claim 18, wherein the photovoltaic cell comprises at least one of:
a double-junction solar cell comprising one or two of a-Si, a-SiGe, mx-Si, nc-Si, CdTe, CuInSe2, and CuInGaSe2 based solar cells;
a triple-junction solar cell comprising one or more of a-Si, a-SiGe, mx-Si, nc-Si, CdTe, CuInSe2, and CuInGaSe2 based solar cells; or
a quadruple-junction solar cell comprising one or more of a-Si, a-SiGe, mx-Si, nc-Si, CdTe. CuInSe2, and CuInGaSe2 based solar cells.

20. A method of making a photoelectrode comprising:
selecting a substrate that is transparent and insulating;
forming a transparent conducting layer on the substrate as a front electrode (Electrode A) for a photovoltaic cell;
forming at least one of single-junction semiconductor pn or pin layers, or multiple-junction stacked pin or pin layers, that generate photovoltage under illumination;
forming a back contact layer which is electrically conductive to form a back contact (Electrode B), which may be either cathode or anode but is opposite to Electrode A;
forming an insulating layer that covers portions of the back contact (Electrode B);
forming a conducting layer that is electrically connected to the transparent conducting layer (Electrode A), the conducting layer being either anode or cathode depending on the polarity of the photovoltaic cell, but being opposite to Electrode B; and, optionally,
forming an oxygen evolution reaction layer and an hydrogen evolution reaction layer to cover all or portions of the anode and the cathode, respectively, and to protect the photovoltaic cell from chemical and electrochemical corrosion.

21. The method of claim 20, wherein at least one of the transparent conducting layer, photovoltaic layers, and the back-contact layer are electrically separated into smaller-area subcells with each subcell group containing both anode and cathode, so that the photoelectrode is functionally separated into a multiple of sub-photoelectrodes.

22. The method of claim 21, wherein the subcells are separated by scribe lines.

23. The method of claim 22, wherein the scribe lines are formed by at least one of laser scribing, mechanical scribing, or chemical scribing by screen-printing of chemical etching paste.

24. The method of claim 22, comprising:
conducting a first scribing which removes predetermined portions of the front contact layer from the insulating substrate, thus electrically isolating the front contact layer into subcells;
conducting a second scribing which removes predetermined portions of the thin-film semiconductor layers;
conducting a third scribing which removes predetermined portions of the back metal contact layer from the semiconductor layers;
the first, second and third scribings being scribed adjacent to one another, thereby connecting the front contact layer of one strip cell with the back contact of a neighboring strip cell;
conducting a fourth scribing, which removes predetermined portions of the back metal contact from the thin-film semiconductor layers approximately at or near the position of the first scribe line, such that a segment between the third and fourth scribe lines is electrically connected to the front electrode (Electrode A) and is electrically isolated from rest of the back contact Electrode B); and, optionally
forming at least one catalyst layer for electrolysis which is applied onto, or electrically connected with, selected areas of the anode or the cathode.

25. A method of claim 24, wherein:
the photovoltaic cells comprises solar cells that do not generate sufficient voltage for water electrolysis under illumination,
the fourth scribing is applied for at least certain subcells, connecting at least two subcells into a unit cell, which, with added voltage from a multiple of subcells connected together, has voltage sufficient to drive water electrolysis; and
covering predetermined areas of the back contact with an insulating layer so that surfaces not resistant to corrosion are protected.

26. The method of 25, wherein the solar cells comprise at least one of single-junction solar cell or low-voltage double-junction solar cells.

27. The method of claim 26, wherein the photovoltaic cell comprises at least one of:
single-junction thin-film silicon based solar cells;
single-junction (SJ) polycrystalline solar cells; or
double-junction solar cells.

28. The method of claim 27, wherein the single-junction thin-film silicon based solar cells comprise at least one of single-junction (SJ) amorphous silicon (a-Si), SJ amorphous silicon germaninum (a-SiGe), SJ microcrystalline silicon (mx-Si), SJ nanocrystalline silicon (nc-Si).

29. The method of claim 27, wherein the single-junction (SJ) polycrystalline solar cells comprise at least one of SJ cadmium telluride based solar cells, SJ CunSe2 based solar cells, SJ CuInGaSe2 based solar cells.

30. The method of claim 27, wherein the double-junction solar cells comprise at least one or two of a-Si, a-SiGe, mx-Si, nc-Si, CdTe, CulInSe2, and CuInGaSe2 based solar cells.

31. The method of claim 24, wherein:
the photovoltaic cells comprise solar cells that do generate sufficient voltage for water electrolysis under illumination,
the fourth scribing is applied for every subcell, and
an appropriate insulating layer covers predetermined areas of the back contact so that surfaces not resistant to corrosion are protected.

32. The method of claim 31, wherein the solar cells comprise at least one of triple-junction solar cells or high-voltage double-junction solar cells.

33. The method of claim 32, wherein the photovoltaic cell comprises at least one of:
a double-junction solar cell comprising one or two of a-Si, a-SiGe, mx-Si, nc-Si, CdTe, CuInSe2, and CuInGaSe2 based solar cells;
a triple-junction solar cell comprising one or more of a-Si, a-SiGe, mx-Si, nc-Si, CdTe, CuInSe2, and CuInGaSe2 based solar cells, or
a quadruple-junction solar cell comprising one or more of a-Si, a-SiGe, mx-Si, nc-Si, CdTe, CuInSe2, and CuInGaSe2 based solar cells.

34. The method of claim 33, wherein the multiple-junction thin-film silicon based solar cells comprise a double-junction solar cell comprising one or two of a-Si, a-SiGe, mx-Si, nc-Si, CdTe, CuInSe2, and CuInGaSe2 based solar cells;

35. The method of claim 33, wherein the multiple-junction solar cells comprise a triple-junction solar cell comprising one or more of a-Si, a-SiGe, mx-Si, nc-Si, CdTe, CuInSe2, and CuInGaSe2 based solar cells.

36. The method of claim 33, wherein the multiple-junction solar cells comprise a quadruple-junction solar cell comprising one or more of a-Si, a-SiGe, mx-Si, nc-Si, CdTe, CuInSe2, and CuInGaSe2 based solar cells.

37. A photoelectrochemical cell comprising
a photoelectrode,
an electrolyte, either alkaline or acidic, with which both anode and cathode are in contact;
compartments for oxidation reaction where oxygen is generated;
compartments for reduction reaction where hydrogen is generated;
ion conduction layers placed between a oxidation compartment and a reduction compartment; and
an enclosure that confines the electrolyte for electrolysis.

38. A method that uses the photoelectrochemical cell of claim 37 to produce hydrogen under radiation from the sun.
